(19) United States
(12) Patent Application Publication
(10) Pub. No.: US 2026/0076078 A1
(43) Pub. Date: Mar. 12, 2026

(54) DISPLAY DEVICE

(71) Applicant: Japan Display Inc., Tokyo (JP)

(72) Inventor: Toshiharu MATSUSHIMA, Tokyo (JP)

(73) Assignee: Japan Display Inc., Tokyo (JP)

(21) Appl. No.: 19/322,952

(22) Filed: Sep. 9, 2025

(30) Foreign Application Priority Data
Sep. 10, 2024 (JP) 2024-156599

(51) Int. Cl. H10K 59/80; G02B 3/00; G02B 5/20; H10K 59/122; H10K 59/38

(52) U.S. Cl. CPC H10K 59/879; G02B 3/005; G02B 5/201; H10K 59/122; H10K 59/38

(57) ABSTRACT

According to one embodiment, a display device includes a substrate, a first display element provided above the substrate and configured to emit light of a first color, a second display element provided above the substrate, arranged with the first display element. and configured to emit light of a second color different from the first color, a color filter layer which includes a first color filter provided directly above the second display element and colored in the first color, and a second color filter provided directly above the first display element and colored in the second color, and which is provided above the first display element and the second display element, and a lens overlapping with the first display element and the second display element and formed in a convex shape.

### CROSS-REFERENCE TO RELATED APPLICATION

This application is based upon and claims the benefit of priority from Japanese Patent Application No. 2024-156599, filed Sep. 10, 2024, the entire contents of which are incorporated herein by reference.

### FIELD

Embodiments described herein relate generally to a display device.

### BACKGROUND

In recent years, various types of display devices have been proposed. For example, in display devices installed in vehicles such as automobiles, it is necessary to ensure sufficient luminance of the display device when viewed from the driver's seat or passenger seat.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view showing the display device along III-III line in FIG. 2.

FIG. 4 is a schematic plan view showing an example of the layout of the subpixels of the display device according to the first embodiment.

FIG. 5 is a schematic cross-sectional view showing the display device according to the first embodiment along V-V line in FIG. 4.

FIG. 6 is a schematic plan view showing an example of layout of a light shielding layer of the display device according to the first embodiment.

FIG. 7 is a schematic graph showing a relationship between light transmittance of color filters and the wavelength.

FIG. 8 is a diagram illustrating an effect of the display device according to the present embodiment.

FIG. 9 is a graph showing a relationship between an angle and the luminance.

FIG. 10 is a diagram showing the display device of the present embodiment mounted in a vehicle device.

FIG. 11 is a diagram showing the display device of the present embodiment mounted in the vehicle device.

FIG. 12 is a diagram showing the display device of the present embodiment mounted in the vehicle device.

FIG. 13 is a schematic plan view showing an example of layout of a light shielding layer of a display device according to a second embodiment.

FIG. 14 is a schematic cross-sectional view showing the display device according to a third embodiment along V-V line in FIG. 4.

FIG. 15 is a schematic plan view showing an example of a layout of subpixels of a display device according to a fourth embodiment.

FIG. 16 is a schematic plan view showing an example of a layout of subpixels of a display device according to a fifth embodiment.

FIG. 17 is a schematic plan view showing an example of a layout of subpixels of a display device according to a sixth embodiment.

FIG. 18 is a schematic cross-sectional view showing the display device according to the sixth embodiment along XVIIIa-XVIIIa line and XVIIIb-XVIIIb line in FIG. 17.

### DETAILED DESCRIPTION

In general, according to one embodiment, a display device includes a substrate, a first display element provided above the substrate and configured to emit light of a first color, a second display element provided above the substrate, arranged with the first display element. and configured to emit light of a second color different from the first color, a color filter layer which includes a first color filter provided directly above the second display element and colored in the first color, and a second color filter provided directly above the first display element and colored in the second color, and which is provided above the first display element and the second display element, and a lens overlapping with the first display element and the second display element and formed in a convex shape.

According to the present embodiment, a display device capable of improving luminance in the diagonal direction can be provided.

Several embodiments will be described hereinafter with reference to the accompanying drawings.

The disclosure is merely an example, and proper changes in keeping with the spirit of the disclosure, which are easily conceivable by a person of ordinary skill in the art, come within the scope of the disclosure as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the disclosure. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

For ease of understanding, the X, Y, and Z axes are described in the drawings as necessary. A direction along the X-axis is referred to as an X-direction (first direction), a direction along the Y-axis is referred to as a Y-direction (second direction), and a direction along the Z-axis is referred to as a Z direction or a third direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

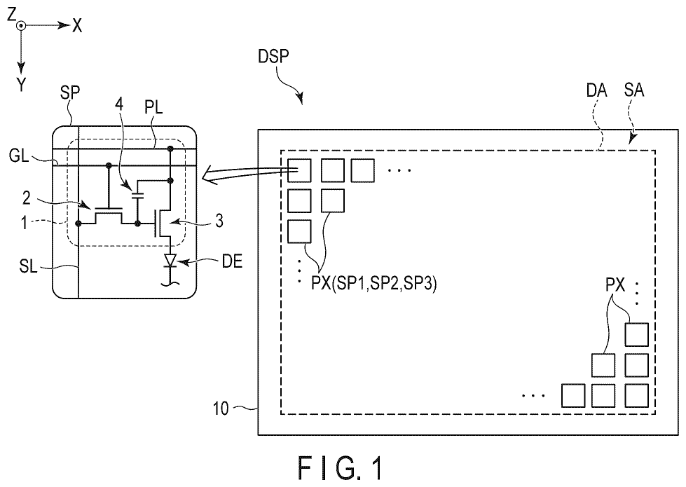

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the present embodiment, the substrate 10 has a rectangular shape elongated in the X-direction in plan view. However, the shape of the substrate 10 in plan view is not limited to a rectangular shape, but may be any other shape such as a square, a circle or an ellipse.

The display area DA comprises a plurality of pixels PX arrayed in matrix in an X-direction and a Y-direction. Each pixel includes a plurality of subpixels SP which display different colors. In the present embodiment, it is assumed that each pixel PX includes a green (first color) subpixel SP1, a blue (second color) subpixel SP2, and a red (third color) subpixel SP3. However, the pixel PX may include a subpixel SP which exhibits another color such as white in addition to subpixels SP1, SP2, and SP3 or instead of one of subpixels SP1, SP2, and SP3.

Each subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL that supply a scanning signal to the pixel circuit 1 of each subpixel SP, a plurality of signal lines SL that supply a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to a scanning line GL. The source electrode of the pixel switch 2 is connected to the signal line SL. The drain electrode of the pixel switch 2 is connected to the gate electrode of the drive transistor 3 and the capacitor 4. The source electrode of the drive transistor 3 is connected to the power line PL and the capacitor 4. The drain electrode of the drive transistor 3 is connected to the display element DE.

Incidentally, the configuration of the pixel circuit 1 is not limited to the example shown in the drawing. For example, the pixel circuit 1 may comprise more thin-film transistors and more capacitors.

Terminals for connecting an IC chip and a flexible printed circuit are provided in the surrounding area SA, which will not be described in detail.

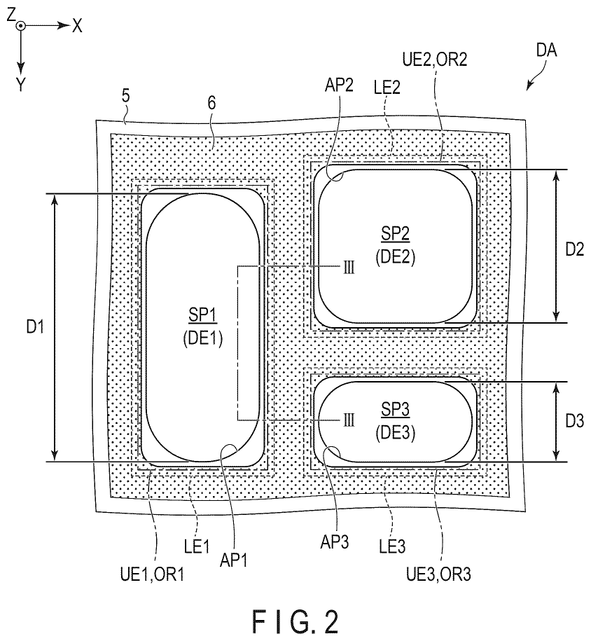

FIG. 2 is a schematic plan view showing an example of a layout of the subpixels SP1, SP2, and SP3. In the example of FIG. 2, each of subpixels SP2 and SP3 is adjacent to subpixel SP1 in the X-direction. Further, subpixels SP2 and SP3 are arranged in the Y-direction. Incidentally, the layout of the subpixels SP1, SP2, and SP3 is not limited to the example of FIG. 2.

A rib layer 5 is provided in the display area DA. The rib layer 5 includes pixel apertures AP1, AP2, and AP3 (first pixel aperture, second pixel aperture, and third pixel aperture) in the subpixels SP1, SP2 and SP3, respectively. In the example of FIG. 2, the pixel aperture AP1 is elongated in the Y-direction relative to the pixel apertures AP2 and AP3. More specifically, a length D1 of the pixel aperture AP1 in the Y-direction is longer than a length D2 of the pixel aperture AP2 in the Y-direction and a length D3 of the pixel aperture AP3 in the Y-direction. Incidentally, the size and shape of the pixel apertures AP1, AP2, and AP3 are not limited to the examples illustrated.

The subpixel SP1 comprises a lower electrode LE1 (first lower electrode), an upper electrode UE1 (first upper electrode), and an organic layer OR1 (first organic layer) each overlapping with the pixel aperture AP1. The subpixel SP2 comprises a lower electrode LE2 (second lower electrode), an upper electrode UE2 (second upper electrode), and an organic layer OR2 (second organic layer) each overlapping with the pixel aperture AP2. The subpixel SP3 comprises a lower electrode LE3, an upper electrode UE3, and an organic layer OR3 each overlapping with the pixel aperture AP3.

Of the lower electrode LE1, the upper electrode UE1 and the organic layer OR1, the portions which overlap with the pixel aperture AP1 constitute the display element (first display element) DE1 of subpixel SP1. The display element DE1 is configured to emit green light. Of the lower electrode LE2, the upper electrode UE2 and the organic layer OR2, the portions which overlap the pixel aperture AP2 constitute the display element (second display element) DE2 of subpixel SP2. The display element DE2 is configured to emit blue light. Of the lower electrode LE3, the upper electrode UE3 and the organic layer OR3, the portions which overlap the pixel aperture AP3 constitute the display element (third display element) DE3 of subpixel SP3. The display element DE1 is configured to emit red light. The display elements DE1, DE2, and DE3 may further include a cap layer to be described below.

The display element DE1 is arranged with the display elements DE2 and DE3 in the X-direction. The display element DE2 is arranged with the display element DE3 in the Y-direction. The rib layer 5 surrounds each of these display elements DE1, DE2, and DE3.

A conductive partition 6 is provided in the display area DA. The partition 6 is located above the rib layer 5 and overlaps the rib layer 5 as a whole. In the example of FIG. 2, the partition 6 has a planar shape similar to that of the rib layer 5. In other words, the partition 6 includes an aperture in each of the subpixels SP1, SP2, and SP3. From another viewpoint, each of the rib layer 5 and the partition 6 has a grating shape as seen in plan view, and surrounds each of the display elements DE1, DE2, and DE3. The partition 6 functions as lines which apply common voltage to the upper electrodes UE1, UE2, and UE3.

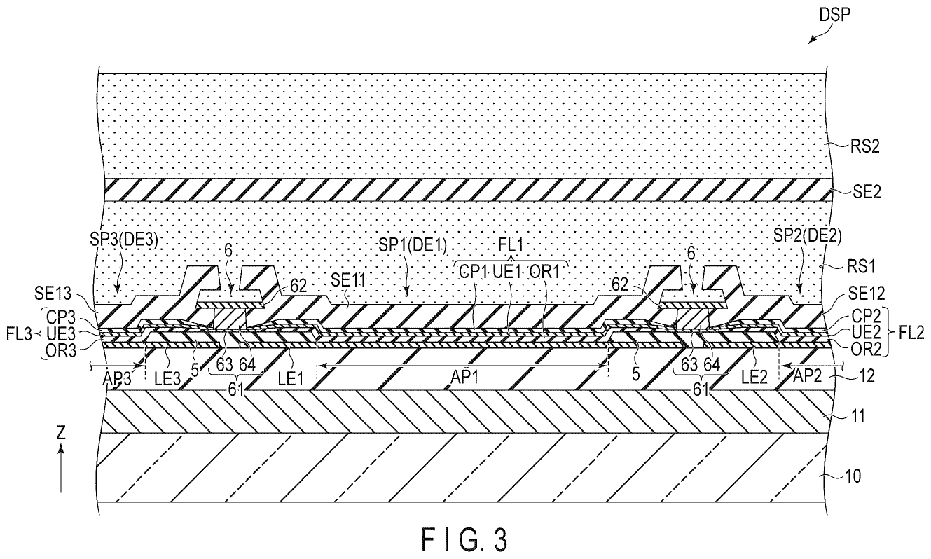

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuits 1, the scanning lines GL, the signal lines SL, and the power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section of FIG. 3, each of the lower electrodes LE1, LE2, and LE3 is connected to the pixel circuit 1 of the circuit layer 11 (i.e., the drain electrode of the drive transistor 3 shown in FIG. 1) through a contact hole provided in the organic insulating layer 12.

The partition 6 includes a conductive lower portion 61 provided on the rib 5 and an upper portion 62 provided on the lower portion 61. The upper portion 62 has a width greater than that of the lower portion 61. Accordingly, the both end parts of the upper portion 62 protrude beyond the side surfaces of the lower portion 61. This shape of the partition 6 is referred to as an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64. In addition, the end portion of the bottom layer 63 is located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with side surfaces of the lower portion 61 of the partition 6.

The display element DE1 includes a cap layer CP1 (first cap layer) which covers the upper electrode UE1. The display element DE2 includes a cap layer CP2 (second cap layer) which covers the upper electrode UE2. The display element DE3 includes a cap layer CP3 which covers the upper electrode UE3. The cap layers CP1, CP2, and CP3 function as optical adjustment layers which improve the extraction efficiency of the light emitted from the organic layers OR1, OR2, and OR3, respectively.

In the following descriptions, a multilayer body including the organic layer OR1, the upper electrode UE1, and the cap layer CP1 is referred to as a stacked film FL1, a multilayer body including the organic layer OR2, the upper electrode UE2, and the cap layer CP2 is referred to as a stacked film FL2, and a multilayer body including the organic layer OR3, the upper electrode UE3, and the cap layer CP3 is referred to as a stacked film FL3.

Sealing layers SE11, SE12, and SE13 (first sealing layers) which cover the stacked films FL1, FL2, and FL3, are provided in the subpixels SP1, SP2, and SP3, respectively. The sealing layer SE11 (first portion) is provided on the cap layer CP1 and continuously covers the display element DE1 and the partition 6 around the display element DE1. The sealing layer SE12 (second portion) is provided on the cap layer CP2 and continuously covers the display element DE2 and the partition 6 around the display element DE2. The sealing layer SE13 (third portion) is provided on the cap layer CP3 and continuously covers the display element DE3 and the partition 6 around the display element DE3.

In the example of FIG. 3, the sealing layer SE11 located on the partition 6 between subpixels SP1 and SP2 is spaced apart from the sealing layer SE12 located on this partition 6. The sealing layer SE11 located on the partition 6 between subpixels SP1 and SP3 is spaced apart from the sealing layer SE13 located on this partition 6. However, two of the sealing layers SE11, SE12, and SE13 may be in contact with each other above the partition 6.

For example, a gap is formed between each of the sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1 (first resin layer). The resin layer RS1 is covered with a sealing layer SE2 (second sealing layer). The sealing layer SE2 is covered with a resin layer RS2 (second resin layer). The resin layers RS1 and RS2 and the sealing layer SE2 are continuously provided in at least the entire display area DA and partly extend to the surrounding area SA. In FIG. 3, elements located above the resin layer RS2 are omitted.

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). In one example, the rib layer 5 is formed of silicon oxynitride, and each of the sealing layers SE11, SE12, SE13, and SE2 is formed of silicon nitride. The resin layers RS1 and RS2 are formed of, for example, a resinous material (organic insulating material) such as epoxy resin or acrylic resin.

Each of the lower electrodes LE1, LE2, and LE3 has a reflective layer, and a pair of conductive oxide layers covering upper and lower surfaces of the reflective layer. The reflective layer can be formed of, for example, a metal material excellent in light reflectivity, such as silver. Each of the conductive oxide layers can be formed of, for example, a transparent conductive oxide such as indium tin oxide (ITO), indium zinc oxide (IZO), or indium gallium zinc oxide (IGZO).

The upper electrodes UE1, UE2, and UE3 are formed of, for example, a metal material such as an alloy (MgAg) of magnesium and silver. For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. In one example, each of the organic layers OR1, OR2, and OR3 comprises a structure in which a hole injection layer, a hole transport layer, an electron blocking layer, a light emitting layer, a hole blocking layer, an electron transport layer and an electron injection layer are stacked in order in the Z-direction. However, each of the organic layers OR1, OR2, and OR3 may comprise an alternative structure such as a so-called tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. In addition, these transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

Each of the bottom layer 63 and the stem layer 64 of the partition 6 is formed of a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or analuminum-silicon alloy (AlSi) can be used. Incidentally, at least one of the bottom layer 63 and the stem layer 64 may comprise a multilayer structure consisting of a plurality of layers. Alternatively, the stem layer 64 may include a layer formed of an insulating material.

For example, the upper portion 62 of the partition 6 has a multilayer structure consisting of a lower layer formed of a metal material and an upper layer formed of conductive oxide. For example, titanium, titanium nitride, molybdenum, tungsten, a molybdenum-tungsten alloy or a molybdenum-niobium alloy can be used as the metal material for forming the lower layer. For example, ITO or IZO can be used as the conductive oxide for forming the upper layer.

Incidentally, the upper portion 62 may have a single-layer structure of a metal material. The upper portion 62 may further include a layer formed of an insulating material.

A common voltage is supplied to the partition 6. This common voltage is supplied to each of the upper electrodes UE1, UE2, and UE3 that are in contact with the side surfaces of the lower portion 61. A pixel voltage is applied to the lower electrodes LE1, LE2 and LE3 through the pixel circuits 1 provided in the subpixels SP1, SP2 and SP3, respectively, based on the video signals of the signal lines SL.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light of the green wavelength range. When a potential difference is formed between the lower electrode LE2 and the upper electrode UE2, the light emitting layer of the organic layer OR2 emits light of the blue wavelength range. When a potential difference is formed between the lower electrode LE3 and the upper electrode UE3, the light emitting layer of the organic layer OR3 emits light in a red wavelength range. The display device DSP may comprise a layer including a quantum dot which generates light exhibiting colors corresponding to the subpixels SP1, SP2, and SP3 by the excitation caused by the light emitted from the light emitting layers.

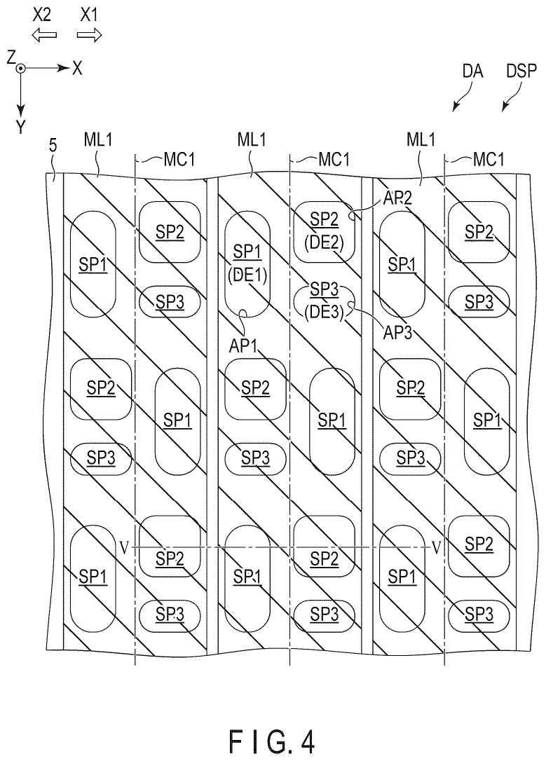

FIG. 4 is a schematic plan view showing an example of a layout of subpixels SP1, SP2, and SP3 of the display device DSP according to the first embodiment. In the example shown in FIG. 4, the subpixels SP1, SP2, and SP3 are arranged in this order in the Y-direction. In addition, the subpixels SP1 and SP2 are alternately arranged in the X-direction, and the subpixels SP1 and SP3 are alternately arranged in the X-direction.

The display device DSP further comprises a plurality of lenses ML1 that are arranged in the X-direction. The lenses ML1 extend in the Y-direction and overlap with the plurality of subpixels SP1, SP2, and SP3 (display elements DE1, DE2, and DE3). In the example shown in FIG. 4, the lenses ML1 overlap with the rows of the subpixels SP1, SP2, and SP3 arranged in the Y-direction and the adjacent rows of the subpixels SP1, SP2, and SP3. The lenses ML1 are cylindrical lenses formed from a transparent resin material such as epoxy resin, acrylic resin, or polyimide resin.

The lens ML1 has center lines MC1. In the example shown in FIG. 4, the center lines MC1 are parallel to the Y-direction. In addition, the center lines MC1 are located between the subpixels SP1 and SP2 adjacent in the X-direction and located between the subpixels SP1 and SP3 adjacent in the X-direction.

As described herein, the center lines MC1 of lens ML1 are lines connecting a plurality of principal points of the lens ML1. The principal points are points where the principal surface of of the lens ML1 is orthogonal to the optical axis. The principal surface is a surface orthogonal to the optical axis, which includes the intersection of incident light rays and emitted light rays when light rays parallel to the optical axis are made incident on the lens ML1.

The directions X1 and X2 shown in FIG. 4 will be described later.

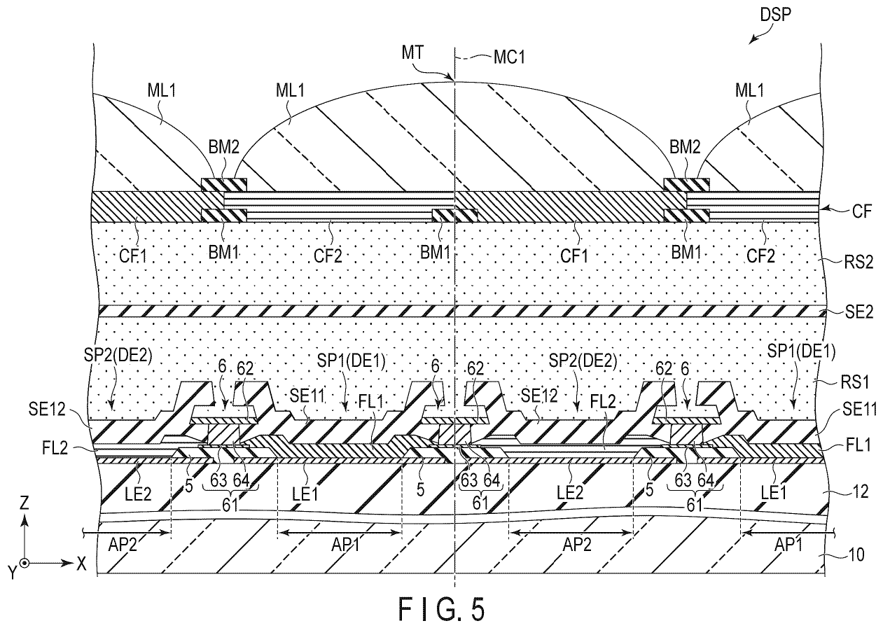

FIG. 5 is a schematic cross-sectional view showing the display device DSP according to the first embodiment along V-V line in FIG. 4. The display device DSP further comprises a color filter layer CF, and light shielding layers BM1 and BM2. The color filter layer CF is provided above the display elements DE1 and DE2. In the example shown in FIG. 5, the color filter layer CF is provided on the resin layer RS2.

The color filter layer CF includes a color filter CF1 (first color filter) formed of a material colored green and a color filter CF2 (second color filter) formed of a material colored blue. The color filter CF1 absorbs light in wavelength ranges other than a green wavelength range. The color filter CF2 absorbs light in wavelength ranges other than the blue wavelength range. In the example shown in FIG. 5, the color filter CF1 is provided directly above the display element DE2, and the color filter CF2 is provided directly above the display element DE1.

The light shielding layer BM1 is provided between the color filter layer CF and the resin layer RS2 and is covered with the color filter layer CF. In the example shown in FIG. 5, the light shielding layer BM1 is provided between the color filters CF1 and CF2 and the resin layer RS2 and is covered with the color filters CF1 and CF2. The light shielding layer BM1 overlaps with the rib layer 5 and the partition 6 in plan view.

The light shielding layer BM2 is covered with the plurality of lenses ML1. In the example shown in FIG. 5, the end portions of the light shielding layer BM2 are covered with the lenses ML1 adjacent in the X-direction. Incidentally, in the illustrated example, the upper surface of the light shielding layer BM2 is exposed from the lenses ML1 adjacent in the X-direction, but may also be completely covered with the lenses ML1 adjacent in the X-direction. The light shielding layer BM2 overlaps with the rib layer 5, the partition 6, and the light shielding layer BM2 in plan view. The light shielding layers BM1 and BM2 are formed of, for example, a resin material with a high light absorption index.

The lens ML1 is formed in a convex shape. In the example shown in FIG. 5, the lens ML1 protrudes on the side opposite to the substrate 10. The lens ML1 overlaps with the color filters CF1 and CF2, the display elements DE1 and DE2, and the pixel apertures AP1 and AP2. In the example shown in FIG. 5, the lens the ML1 is provided above the color filter layer CF and is in contact with the color filter layer CF.

The lens ML1 overlaps with the light shielding layer BM1, the rib layer 5, and the partition 6. In the example shown in FIG. 5, the center line MC1 of the lens ML1 overlaps with the light shielding layer BM1, the rib layer 5, and the partition 6. In addition, a top portion MT of the lens ML1 overlaps with the center line MC1. Therefore, in the example shown in FIG. 5, the top portion MT of the lens ML1 is provided between the color filters CF1 and CF2 and overlaps with the light shielding layer BM1, the rib layer 5, and the partition 6. The lens ML1 is in contact with, for example, an air layer.

Incidentally, the position of the color filter layer CF is not limited to the example shown in FIG. 5. For example, the color filter layer CF may be provided above the lens ML1. In addition, the lens ML1 may be formed in, for example, a convex shape toward the substrate 10. Furthermore, a plurality of resin layers RS2 may be provided between the color filter layer CF and the sealing layer SE2.

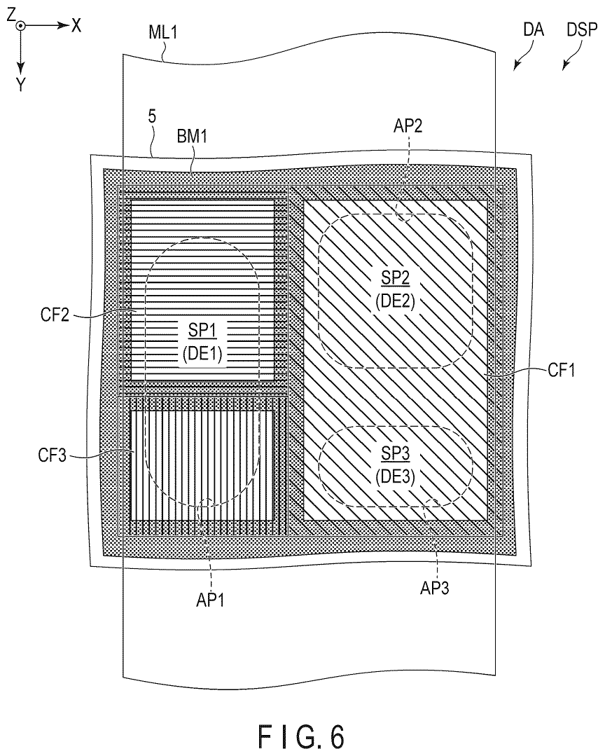

FIG. 6 is a schematic plan view showing an example of a layout of the light shielding layer BM1 of the display device DSP according to the first embodiment. The color filter layer CF includes a color filter CF3 (third color filter) formed of a material colored red, in addition to the above-described color filters CF1 and CF2. The color filter CF3 absorbs light in wavelength ranges other than the red wavelength range. In the example shown in FIG. 6, the color filter CF3 is provided directly above the display element DE1. The color filters CF1, CF2, and CF3 overlap with the lens ML1.

The color filter CF1 is provided directly above the display elements DE2 and DE3. The color filters CF2 and CF3 are provided directly above the display element DE1. In the example shown in FIG. 6, the color filters CF2 and CF3 are arranged with the color filter CF1 in the X-direction. In addition, the color filters CF2 and CF3 are arranged in the Y-direction. In other words, the color filter CF1 is aligned with the display element DE1 in the X-direction, the color filter CF2 is aligned with the display element DE2 in the X-direction, and the color filter CF3 is aligned with the display element DE3 in the X-direction. Peripheral portions of the respective color filters CF1, CF2, and CF3 may overlap with each other or may be separated from each other.

The light shielding layer BM1 is covered with the color filters CF1, CF2, and CF3 and surrounds the color filters CF1, CF2, and CF3. In the example shown in FIG. 6, a part of the light shielding layer BM1 is provided between the color filter CF2 and the color filter CF3 and overlaps with the pixel aperture AP1. In addition, in the example shown in FIG. 6, the light shielding layer BM1 is not provided between the pixel apertures AP2 and AP3.

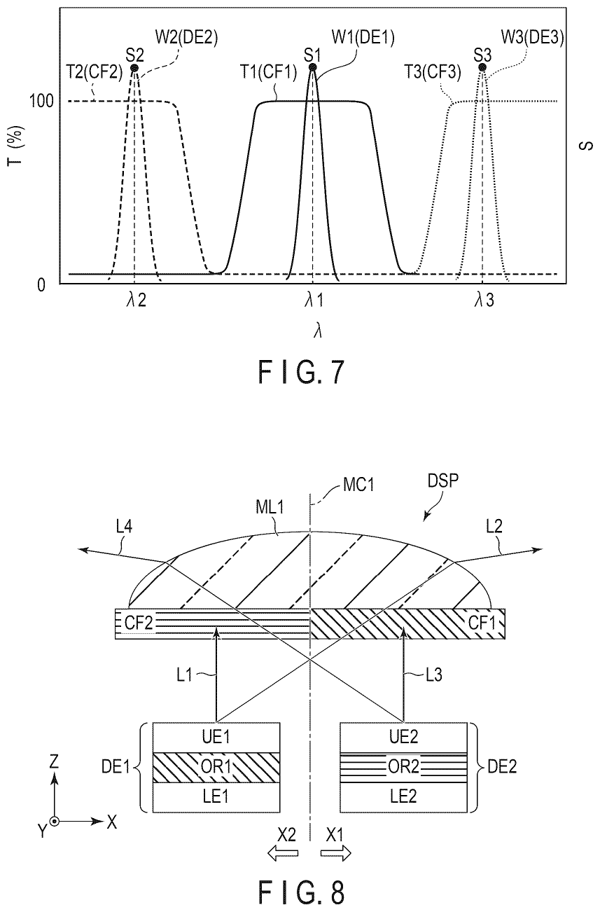

FIG. 7 is a schematic graph showing a relationship between the light transmittance of the color filters CF1, CF2, and CF3 and the wavelength. In the graph shown in FIG. 7, a horizontal axis indicates wavelength λ, a left vertical axis indicates the light transmittance of the color filters CF1, CF2, and CF3, and a right vertical axis indicates the spectral intensity of light emitted from each of the display elements DE1, DE2, and DE3. A curve T1 indicates the light transmittance of the color filter CF1, a curve T2 indicates the light transmittance of the color filter CF2, and a curve T3 indicates the light transmittance of the color filter CF3. A curve W1 indicates the spectral intensity of light emitted from the display element DE1, a curve W2 indicates the spectral intensity of light emitted from the display element DE2, and a curve W3 shows the spectral intensity of light emitted from the display element DE3. A wavelength at which a maximum spectral intensity S1 occurs in the curve W1 is referred to as a wavelength λ1, a wavelength at which a maximum spectral intensity S2 occurs in the curve W2 is referred to as a wavelength λ2, and a wavelength at which a maximum spectral intensity S3 occurs in the curve W3 is referred to as a wavelength λ3.

As shown in FIG. 7, the light transmittance T of the color filter CF1 at the wavelength λ1 is approximately 100%. In contrast, the light transmittance T of the color filter CF1 at the wavelengths λ2 and λ3 is lower than the light transmittance T of the color filter CF1 at the wavelength λ1. In other words, the light emitted from the display element DE1 hardly attenuates but passes through the color filter CF1, but the light emitted from the display elements DE2 and DE3 is absorbed by the color filter CF1 and hardly passes through the color filter CF1.

Similarly, as shown in FIG. 7, the light transmittance T of the color filter CF2 at the wavelength λ2 is approximately 100%. In contrast, the light transmittance T of the color filter CF2 at the wavelengths λ1 and λ3 is lower than the light transmittance T of the color filter CF2 at the wavelength λ2. In other words, the light emitted from the display element DE2 hardly attenuates but passes through the color filter CF2, but the light emitted from the display elements DE1 and DE3 is absorbed by the color filter CF2 and hardly passes through the color filter CF2.

Similarly, as shown in FIG. 7, the light transmittance T of the color filter CF3 at the wavelength λ3 is approximately 100%. In contrast, the light transmittance T of the color filter CF3 at the wavelengths λ1 and λ2 is lower than the light transmittance T of the color filter CF3 at the wavelength λ3. In other words, the light emitted from the display element DE3 hardly attenuates but passes through the color filter CF3, but the light emitted from the display elements DE1 and DE2 is absorbed by the color filter CF3 and hardly passes through the color filter CF3.

Next, an effect of the display device DSP according to the present embodiment will be described with reference to FIG. 8. FIG. 8 is a diagram illustrating the effect of the display device DSP according to the present embodiment. In the following descriptions, a direction along the X-direction from the display element DE1 toward the center line MC1 is referred to as a direction X1, and a direction along the X-direction from the display element DE2 toward the center line MC1 is referred to as a direction X2.

As described above, the color filter CF2 is provided directly above the display element DE1, and the color filter CF1 is provided directly above display element DE2. The display element DE1 emits light in the green wavelength range, and the display element DE2 emits light in the blue wavelength range. In contrast, the color filter CF1 absorbs light in wavelength ranges other than the green wavelength range, and the color filter CF2 absorbs light in wavelength ranges other than the blue wavelength range.

Therefore, a light beam L1 emitted from the display element DE1 in the front direction (Z-direction) is absorbed by the color filter CF2. In contrast, a light beam L2 emitted from the display element DE1 in a diagonal direction (a direction inclined toward the direction X1 side relative to the Z-direction) is hardly absorbed by the color filter CF1 and passes through the color filter CF1. The light beam L2 travels through the lens ML1, refracts on the curved surface of the lens ML1, and reaches user's eyes. Similarly, a light beam L3 emitted from the display element DE2 in the front direction is absorbed by the color filter CF1. In contrast, a light beam L4 emitted from the display element DE2 in a diagonal direction (a direction inclined toward the direction X2 relative to the Z-direction) is hardly absorbed by the color filter CF2 and passes through the color filter CF2. The light beam L4 travels through the lens ML1, refracts on the curved surface of the lens ML1, and reaches user's eyes. Although not shown in the figure, the display element DE3 is configured in the same manner.

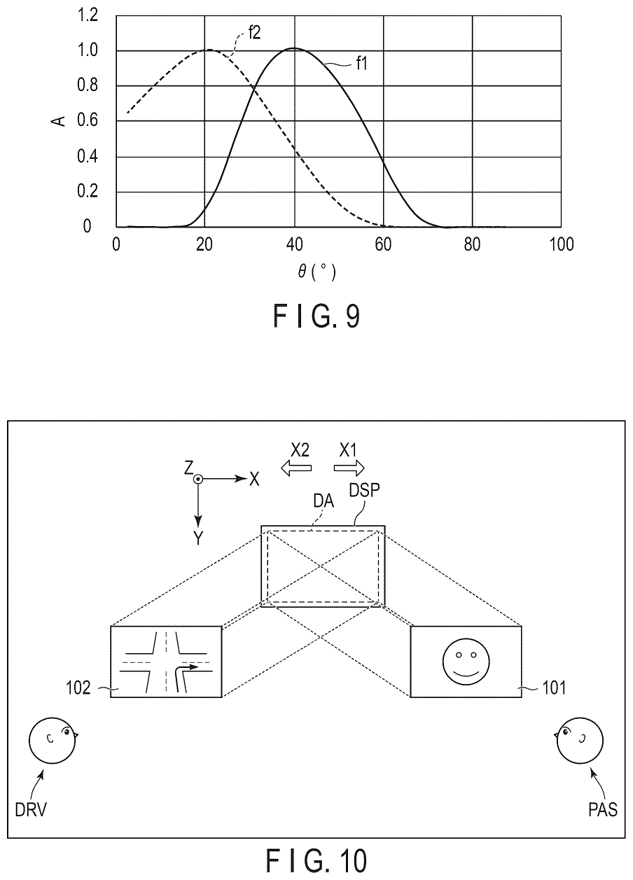

FIG. 9 is a graph showing a relationship between the angle θ and the luminance A. In the graph shown in FIG. 9, a horizontal axis indicates the angle θ relative to the Z-direction, and a vertical axis indicates the luminance A when viewed from the angle θ toward the display device DSP. When the angle θ is 0°, it corresponds to viewing the display device DSP from the front side.

A curve f1 represented by a solid line indicates the relationship between the angle θ and the luminance A in the display device DSP according to the present embodiment. A curve f2 represented by a dashed line indicates the relationship between angle θ and the luminance A in a display device DSP according to a comparative example. In the display device DSP of the comparative example, the color filter CF1 is provided directly above the pixel aperture AP1, the color filter CF2 is provided directly above the pixel aperture AP2, and the color filter CF3 is provided above the pixel aperture AP3. In FIG. 9, a maximum value of the luminance A in the display device DSP of the comparative example (curve f2) is set to 1.

In the curve f1, the luminance A is maximum when the angle θ is approximately 40°. In contrast, in the curve f2, the luminance A is maximum when the angle θ is approximately 20°. In addition, the maximum value of the luminance A in the curve f1 is equal to the maximum value of the luminance A in the curve f2.

In other words, in the display device DSP according to the present embodiment, as described above, light in the front direction is absorbed by the color filter, but light in the oblique direction is not absorbed by the color filter and is transmitted through the color filter. Therefore, in the present embodiment, it is possible to improve the luminance A of the display device DSP when viewed from the oblique direction compared to the display device DSP according to the comparative example. In addition, since the color filters allow light from the oblique direction to pass through the color filters, the viewing angle of the display device DSP can be widened.

In addition, the light emitted from the display elements DE1 in the direction inclined toward the Y-direction relative to the Z-direction is absorbed by the color filters CF2 and CF3. Similarly, the light emitted from the display elements DE2 and DE3 in the same direction is absorbed by the color filter CF1. The viewing angle in the Y-direction can be thereby limited. For example, when the display device DSP is installed in a vehicle, reflection of the displayed image on the front windshield of the vehicle can be suppressed by limiting the viewing angle in the Y-direction.

Furthermore, in the display device DSP according to the present embodiment, the lens ML1 is provided on the color filter layer CF. In addition, the sealing layers SE11, SE12, SE13, and SE2 and the resin layers RS1 and RS2 are stacked between the display elements DE1, DE2, and DE3 and the color filter layer CF. Therefore, the amount of light absorbed by the color filter layer CF, of the light emitted from the display elements DE1, DE2, and DE3 in the oblique direction, can be reduced. The luminance of the display device DSP can be thereby improved.

Next, installing the display device DSP of the present embodiment in a vehicle such as an automobile will be described. FIG. 10 to FIG. 12 are diagrams showing the display device DSP of the present embodiment installed in a vehicle device. In one example, installing the display device DSP between a driver's seat and a passenger seat will be described.

As shown in FIG. 10, for example, it is required to allow different images to be viewed from the driver's seat side and the passenger seat side while the vehicle is in motion. In this case, the driver's seat is located on the direction X2 side of the display device DSP, and the passenger seat is located on the X1 direction X1 side of the display device DSP. When the display elements DE1, DE2, and DE3 are provided as shown in the example of FIG. 4, a passenger PAS in the passenger seat can visually recognize the light emitted from the display elements DE1, DE2, and DE3 that are on the direction X2 side of the center line MC1, among the display elements DE1, DE2, and DE3 that overlap with the lens ML1. In contrast, a driver DRV seated in the driver's seat can visually recognize the light emitted from the display elements DE1, DE2, and DE3 in the direction X1 side of the center line MC1, among the display elements DE1, DE2, and DE3 that overlap with the lens ML1. Therefore, image signals for displaying images for the passenger PAS in the passenger's seat are supplied to the display elements DE1, DE2, and DE3 on the direction X2 side of the center line MC1, and image signals for displaying images for the driver DRV are supplied to the display elements DE1, DE2, and DE3 on the direction X1 side of the center line MC1. Accordingly, the passenger PAS in the passenger seat and the driver DRV can visually recognize screens 101 and 102 on which different images are displayed, respectively.

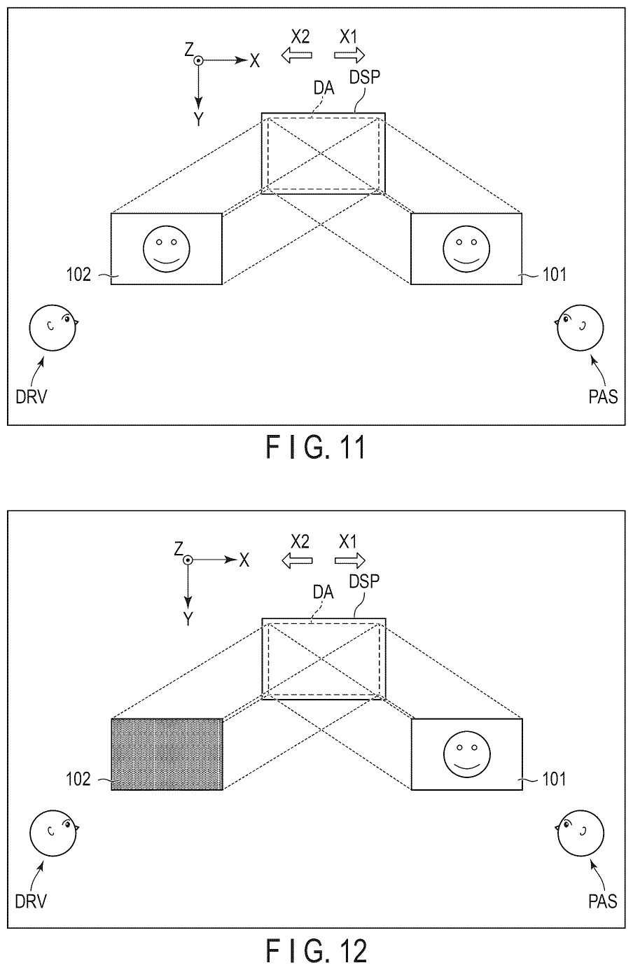

As shown in FIG. 11, for example, when an engine is off and visually recognizing the same image on both the driver's seat side and the passenger seat side is desirable, the same image signal is supplied to the display elements DE1, DE2, and DE3 on the direction X1 side of the center line MC1 and to the display elements DE1, DE2, and DE3 on the direction X2 side of the center line MC1. Accordingly, the passenger PAS in the passenger seat and the driver DRV can visually recognize screens 101 and 102 on which the same images are displayed, respectively.

As shown in FIG. 12, for example, if making it difficult to visually recognize an image from the driver's seat side while allowing an image to be visually recognized from the passenger seat side, during driving, an image signal is supplied to the display elements DE1, DE2, and DE3 on the direction X2 side of the center line MC1, while no image signal is supplied to the display elements DE1, DE2, and DE3 on the direction X1 side of the center line MC1. As a result, the display elements DE1, DE2, and DE3 on the direction X2 side of the center line MC1 are turned on in response to the image signal, while the display elements DE1, DE2, and DE3 on the direction X1 side of the center line MC1 are not turned on. Accordingly, the passenger PAS in the passenger seat can visually recognize a screen 101 on which the image is displayed, while the driver DRV can visually recognize a screen 102 where the image is hardly displayed.

### Second Embodiment

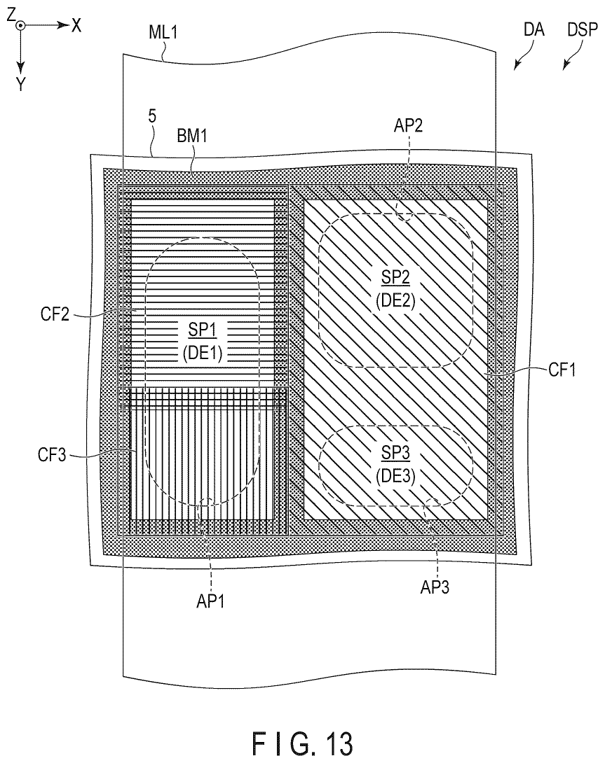

FIG. 13 is a schematic plan view showing an example of a layout of a light shielding layer BM1 of a display device DSP according to a second embodiment. The elements which are the same as or similar to the elements of the first embodiment are denoted by the same reference numerals, and duplicated descriptions are omitted as appropriate.

In the display device DSP according to the second embodiment, unlike the display device DSP according to the first embodiment shown in FIG. 6, the light shielding layer BM1 is not provided between the color filters CF2 and CF3 and does not overlap with the display element DE1. In addition, parts of the color filters CF2 and CF3 overlap directly above the display element DE1. In other words, the display element DE1 is completely covered with the color filters CF2 and CF3.

Thus, even when the light shielding layer BM1 is not provided between the color filters CF2 and CF3, the display element DE1 is completely covered with the color filters CF2 and CF3, causing most of the light emitted from the display element DE1 in the Z-direction to be absorbed by the color filters CF2 and CF3. The luminance of the display device DSP in the front direction can be thereby reduced.

The same effects as those obtained in the display device DSP according to the first embodiment can also be obtained in the display device DSP according to the second embodiment.

### Third Embodiment

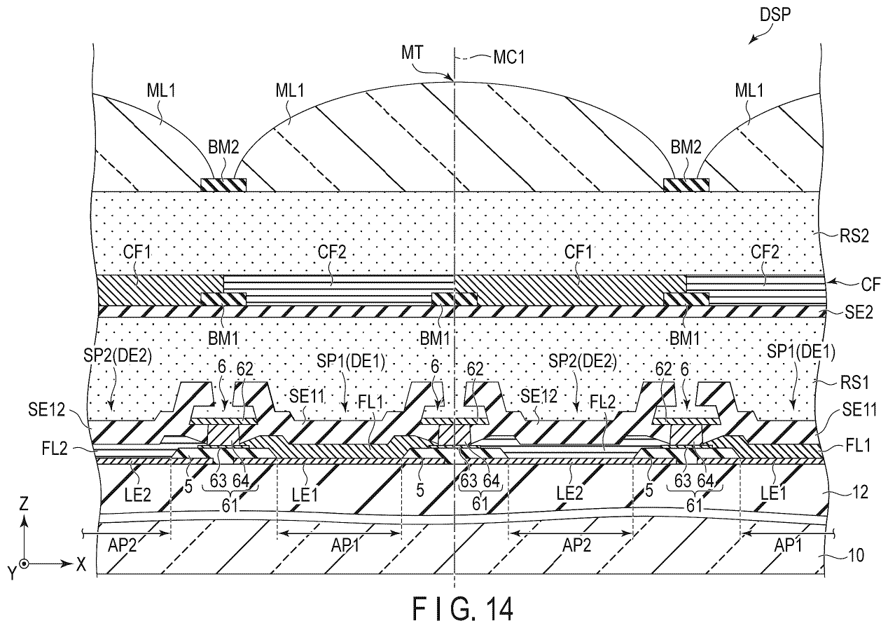

FIG. 14 is a schematic cross-sectional view showing a display device DSP according to a third embodiment along V-V line in FIG. 4. In the display device DSP according to the third embodiment, the color filter layer CF is provided on the sealing layer SE2. In the example shown in FIG. 14, a light shielding layer BM1 is provided between the color filter layer CF and the sealing layer SE2. The color filter CF is covered with the second resin layer RS2. A lens ML1 and the light shielding layer BM2 are provided on the resin layer RS2.

The same effects as those obtained in the display device DSP according to each of the above-described embodiments can also be obtained in the display device DSP according to the third embodiment.

### Fourth Embodiment

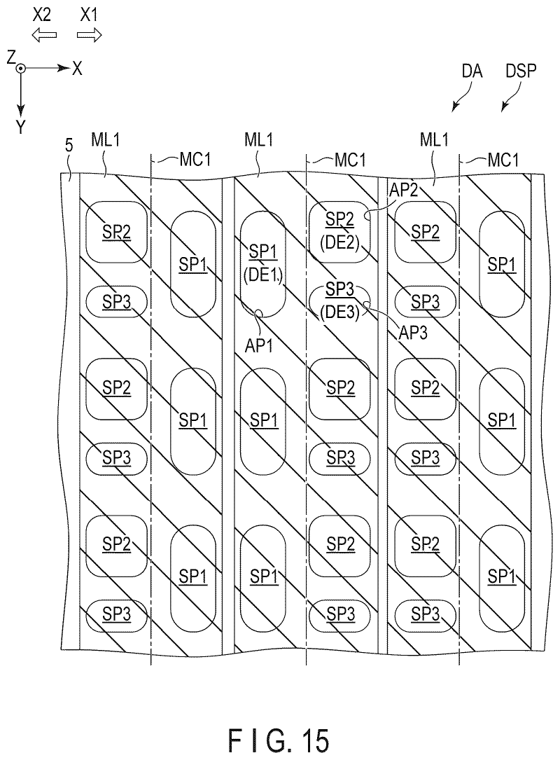

FIG. 15 is a schematic plan view showing an example of a layout of subpixels SP1, SP2, and SP3 of a display device DSP according to a fourth embodiment.

In the example shown in FIG. 15, a first row of subpixels SP1 arranged in the Y-direction and a second row of subpixels SP2 and SP3 arranged alternately in the Y-direction are formed. Two second rows are arranged between the first rows adjacent in the X-direction. A lens ML1 overlaps with the first row and the second row. Center lines MC1 are located between the subpixels SP1 and SP2 adjacent in the X-direction and located between the subpixels SP1 and SP3 adjacent in the X-direction.

When the display elements DE1, DE2, and DE3 are provided as shown in the example of FIG. 15, image signals for displaying images for the passenger PAS in the passenger's seat are supplied to the display elements DE1, DE2, and DE3 on the direction X2 side of the center line MC1, and image signals for displaying images for the driver DRV are supplied to the display elements DE1, DE2, and DE3 on the direction X1 side of the center line MC1. Accordingly, the passenger PAS in the passenger seat and the driver DRV can visually recognize screens 101 and 102 on which different images are displayed, respectively.

The same effects as those obtained in the display device DSP according to each of the above-described embodiments can also be obtained in the display device DSP according to the fourth embodiment.

### Fifth Embodiment

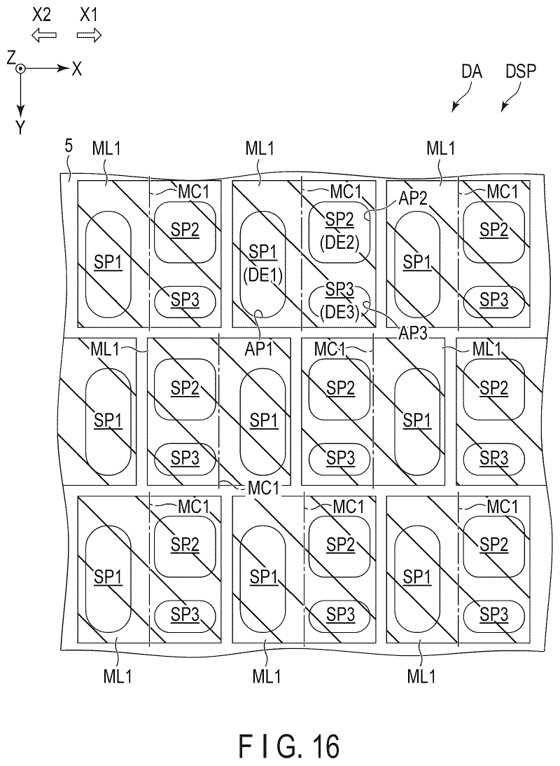

FIG. 16 is a schematic plan view showing an example of a layout of subpixels SP1, SP2, and SP3 of a display device DSP according to a fifth embodiment. In the example shown in FIG. 16, a row of subpixels SP1 arranged in the Y-direction and a row of subpixels SP2 and SP3 alternately arranged in the Y-direction are alternately arranged in the X-direction.

In the display devices DSP according to the first and fourth embodiments, a plurality of subpixels SP1, SP2, and SP3 overlap with a single lens ML1. In contrast, in the display device DSP according to the fifth embodiment, a set of subpixels SP1, SP2, and SP3 overlaps with one lens ML1.

In a display area DA, a third row in which a plurality of lenses ML1 are arranged in the X-direction, and a fourth row in which a plurality of lenses ML1 are arranged in the X-direction and are adjacent to the third row in the Y-direction, are formed. The lenses ML1 in the third row overlap with the subpixels SP1 on the direction X2 side of the center line MC1 and overlap with the subpixels SP2 and SP3 on the direction X1 side of the center line MC1. The lenses ML1 in the fourth row overlap with the subpixels SP2 and SP3 on the direction X2 side of the center line MC1 and overlap with the subpixel SP1 on the direction X1 side of the center line MC1. The third and fourth rows are arranged alternately in the Y-direction.

When the display elements DE1, DE2, and DE3 are provided as shown in the example of FIG. 16, image signals for displaying images for the passenger PAS in the passenger's seat are supplied to the display elements DE1, DE2, and DE3 on the direction X2 side of the center line MC1, and image signals for displaying images for the driver DRV are supplied to the display elements DE1, DE2, and DE3 on the direction X1 side of the center line MC1. Accordingly, the passenger PAS in the passenger seat and the driver DRV can visually recognize screens 101 and 102 on which different images are displayed, respectively.

The same effects as those obtained in the display device DSP according to each of the above-described embodiments can also be obtained in the display device DSP according to the fifth embodiment.

### Sixth Embodiment

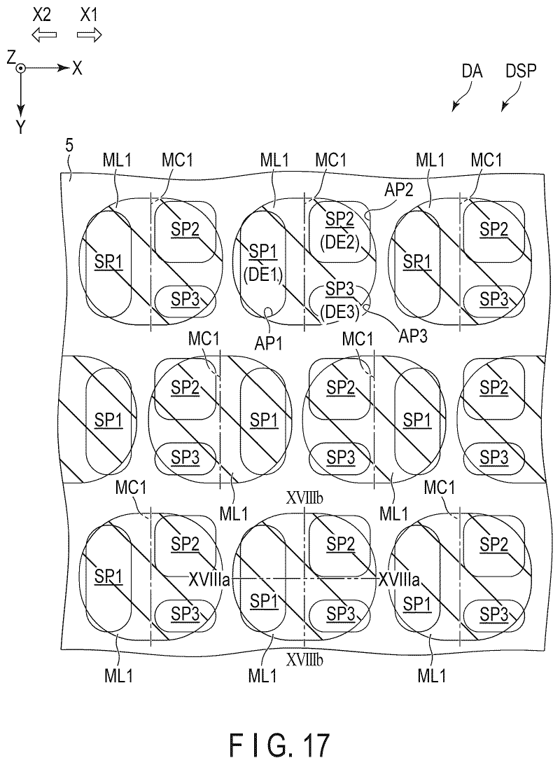

FIG. 17 is a schematic plan view showing an example of a layout of subpixels SP1, SP2, and SP3 of a display device DSP according to a sixth embodiment. The layout of the subpixels SP1, SP2, and SP3 and the lens ML1 is the same as that of the fifth embodiment shown in FIG. 17.

In the display device DSP according to the sixth embodiment, unlike each of the above-described embodiments, corners of the lens ML1 are formed in a rounded shape. Incidentally, the lens ML1 may be formed in a circular or elliptical shape in plan view.

In the example shown in FIG. 17, parts of the subpixels SP1, SP2, and SP3 are not covered with the lens ML1, but these parts may be completely covered with the lens ML1. In addition, these parts may be covered with, for example, a light shielding layer BM2 (not shown).

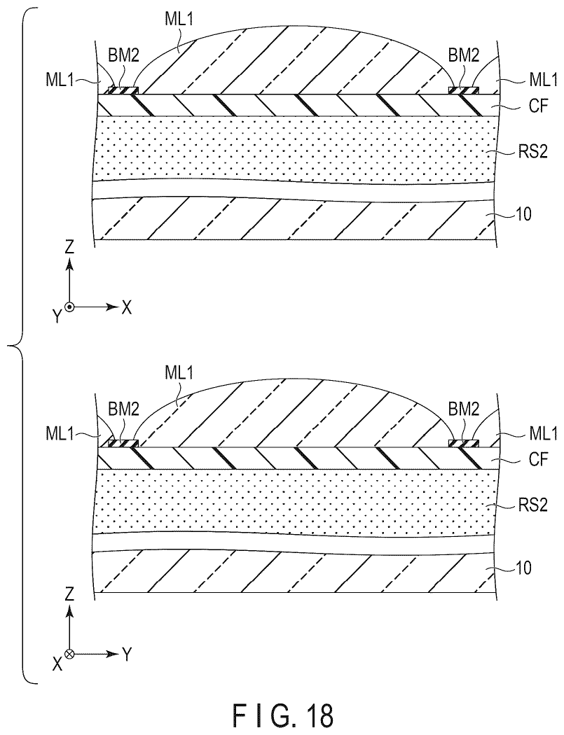

FIG. 18 is a schematic cross-sectional view showing the display device DSP according to the sixth embodiment along XVIIIa-XVIIIa line and XVIIIb-XVIIIb line in FIG. 17. The figure shown on the upper side of FIG. 18 is a cross-sectional view of the display device DSP along XVIIIa-XVIIIa line. The cross-sectional shape of the lens ML1 in the X-direction is a convex shape protruding toward the side opposite to the substrate 10.

The figure shown on the lower side of FIG. 18 is a cross-sectional view of the display device DSP along XVIIIb-XVIIIb line. The cross-sectional shape of the lens ML1 in the Y-direction is a convex shape protruding toward the side opposite to the substrate 10. Therefore, the viewing angle in the Y-direction is restricted. For example, when the display device DSP is installed in a vehicle, reflection of the displayed image on the front windshield of the vehicle can be suppressed by limiting the viewing angle in the Y-direction.

The same effects as those obtained in the display device DSP according to each of the above-described embodiments can also be obtained in the display device DSP according to the sixth embodiment.

All of the display devices that can be implemented by a person of ordinary skill in the art through arbitrary design changes to the display device described above as the embodiments of the present invention come within the scope of the present invention as long as they are in keeping with the spirit of the present invention.

Various modified examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device comprising:
a substrate;
a first display element provided above the substrate and configured to emit light of a first color;
a second display element provided above the substrate, arranged with the first display element, and configured to emit light of a second color different from the first color;
a color filter layer which includes a first color filter provided directly above the second display element and colored in the first color, and a second color filter provided directly above the first display element and colored in the second color, and which is provided above the first display element and the second display element; and
a lens overlapping with the first display element and the second display element and formed in a convex shape.

2. The display device of claim 1, wherein
the lens protrudes toward a side opposite to the substrate and is provided above the color filter layer.

3. The display device of claim 2, wherein
the lens is in contact with the color filter layer.

4. The display device of claim 1, wherein
a top portion of the lens is located between the first color filter and the second color filter.

5. The display device of claim 1, further comprising:
a light shielding layer covered with the first color filter and the second color filter.

6. The display device of claim 5, wherein
a top portion of the lens overlaps with the light shielding layer.

7. The display device of claim 1, wherein
the first display element and the second display element are arranged in a first direction, and
the lens is a cylindrical lens extending in a second direction intersecting the first direction.

8. The display device of claim 1, wherein
the first display element and the second display element are arranged in a first direction, and
a cross-sectional shape of the lens along the first direction and a second direction intersecting the first direction is a convex shape protruding toward a side opposite to the substrate.

9. The display device of claim 1, further comprising:
a third display element provided above the substrate and configured to emit light of a third color different from the first color and the second color, wherein
the first display element is arranged with the second display element and the third display element in a first direction,
the second display element is arranged with the third display element in a second direction intersecting the first direction,
the color filter layer further includes a third color filter provided directly above the first display element and colored in the third color,
the first color filter is provided directly above the third display element,
the second color filter is arranged with the second display element in the first direction,
the third color filter is arranged with the second color filter in the second direction and arranged with the third display element in the first direction, and
the lens overlaps with the third color filter.

10. The display device of claim 9, further comprising:
a light shielding layer covered with the first color filter, the second color filter, and the third color filter.

11. The display device of claim 10, wherein
the light shielding layer is provided between the second color filter and the third color filter and overlaps with the first display element.

12. The display device of claim 10, wherein
the light shielding layer does not overlap with the first display element, and
the first display element is completely covered with the second color filter and the third color filter.

13. The display device of claim 12, wherein
the second color filter overlaps with at least a part of the third color filter directly above the first display element.

14. The display device of claim 10, wherein
the light shielding layer is not provided between the second display element and the third display element.

15. The display device of claim 9, further comprising:
a rib layer including a first pixel aperture overlapping with the first display element, a second pixel aperture overlapping with the second display element, and a third pixel aperture overlapping with the third display element, wherein
the first pixel aperture is more elongated in the second direction than the second pixel aperture and the third pixel aperture.

16. The display device of claim 1, further comprising:
a rib layer including a first pixel aperture overlapping with the first display element and a second pixel aperture overlapping with the second display element, and formed of an inorganic material;
a partition including a conductive lower portion provided on the rib layer, and an upper portion provided on the lower portion to protrude from a side surface of the lower portion; and
a first sealing layer provided above the partition and formed of an inorganic material, wherein
the first display element includes:
a first lower electrode provided above the substrate;
a first organic layer provided on the first lower electrode to be in contact with the first lower electrode through the first pixel aperture;
a first upper electrode provided on the first organic layer; and
a first cap layer provided on the first upper electrode,
the second display element includes:
a second lower electrode provided above the substrate;
a second organic layer provided on the second lower electrode to be in contact with the second lower electrode through the second pixel aperture;
a second upper electrode provided on the second organic layer; and
a second cap layer provided on the second upper electrode,
the first sealing layer includes a first portion provided on the first cap layer, and a second portion spaced apart from the first portion and provided on the second cap layer, and
the first upper electrode and the second upper electrode are in contact with the lower portion.

17. The display device of claim 16, wherein
a top portion of the lens overlaps with the rib layer and the partition.

18. The display device of claim 16, further comprising:
a first resin layer provided on the first sealing layer;
a second sealing layer provided on the first resin layer and formed of an inorganic material; and
a second resin layer provided above the second sealing layer.

19. The display device of claim 18, wherein
the color filter layer is provided between the second sealing layer and the second resin layer, and
the lens is provided on the second resin layer.

20. The display device of claim 18, wherein
the color filter layer is provided between the second resin layer and the lens.
